(19) United States
(12) Patent Application Publication
(10) Pub. No.: US 2016/0006422 A1
(43) Pub. Date: Jan. 7, 2016

(54) LOW POWER FREQUENCY DIVIDER USING DYNAMIC MODULATED-LOAD LATCH

(71) Applicant: QUALCOMM Incorporated, San Jose, CA (US)

(72) Inventors: Thinh Cat Nguyen, San Jose, CA (US); Jeongsik Yang, San Jose, CA (US); Shen Wang, Palo Alto, CA (US); Ara Bicakci, Belmont, CA (US); Anup Savla, Santa Clara, CA (US); Babak Vakili-Amini, Irvine, CA (US)

(21) Appl. No.: 14/322,603

(22) Filed: Jul. 2, 2014

(51) Int. Cl. H03K 3/356; H03K 3/012

(52) U.S. Cl. CPC H03K 3/356; H03K 3/012

(57) ABSTRACT

A dynamic latch is disclosed that may reduce power consumption in frequency dividers while widening their frequency operation ranges. The dynamic latch includes a sense component to detect an input voltage in response to a first state of a mode select signal, and to generate an output voltage based, at least in part, on the input voltage; a hold component to retain the output voltage in response to a second state of the mode select signal; and a first transistor, coupled between the sense component and ground potential, including a gate responsive to the mode select signal.

### TECHNICAL FIELD

The present embodiments relate generally to frequency dividers, and specifically to low-power latches that may be used to implement frequency dividers.

### BACKGROUND OF RELATED ART

A frequency divider receives an input signal having a predefined frequency f and produces an output signal having a frequency f/n, where n is an integer value. Frequency dividers may be provided along the local oscillator (LO) distribution path in mobile communications systems to produce clock signals at a desired frequency.

Current mode logic (CML) latches are commonly used in frequency divider implementations. CML latches are capable of bimodal operation. For example, a typical CML latch includes one set of transistors to sense or detect an input voltage during a “sensing mode,” and includes another set of transistors to retain a corresponding output voltage during a “holding mode.” The ability to seamlessly switch between sensing and holding a particular voltage makes CML latches well-suited for frequency division.

Conventional CML-based frequency dividers may consume a significant amount of power. For example, a typical CML latch draws a tail current during both the sensing mode and the holding mode. Thus, it would be desirable to reduce the power consumption of CML latches and CML-based frequency dividers.

### SUMMARY

This Summary is provided to introduce in a simplified form a selection of concepts that are further described below in the Detailed Description. This Summary is not intended to identify key features or essential features of the claimed subject matter, nor is it intended to limit the scope of the claimed subject matter.

A dynamic latch is disclosed that may reduce power consumption in frequency dividers. In accordance with the present embodiments, a dynamic latch is disclosed that includes a sense component to detect an input voltage in response to a first state of a mode select signal, and to generate an output voltage based, at least in part, on the input voltage; a hold component to retain the output voltage in response to a second state of the mode select signal; and a first transistor, coupled between the sense component and ground potential, including a gate responsive to the mode select signal. For some embodiments, the dynamic latch is to operate in a sensing mode when the mode select signal is in the first state, and dynamic latch is to operate in a holding mode when the mode select signal is in the second state. The first transistor may provide a tail current based, at least in part, on the mode select signal. Further, for some embodiments, the dynamic latch includes an impedance controller to vary a load impedance of the dynamic latch based, at least in part, on the mode select signal. The impedance controller may decrease the load impedance when the mode select signal is in the first state, and may increase the load impedance when the mode select signal is in the second state.

The impedance controller may include a variable load coupled between a voltage source and the hold component. The impedance of the variable load may be controlled, at least in part, by the mode select signal. For at least one embodiment, the variable load may be implemented by one or more transistors operating in a triode mode.

A number of the dynamic latches may be used to form a frequency divider. For at least some embodiments, the frequency divider includes a first dynamic latch and a second dynamic latch. The first and second dynamic latches may be cross-coupled to one another such that the output voltage of the first dynamic latch is provided as the input voltage to the second dynamic latch, and the output voltage of the second dynamic latch is provided as the input voltage to the first dynamic latch. The sense component of the first dynamic latch may be activated in response to a first transition of a clock signal, and the hold component of the first dynamic latch may be activated in response to a second transition of the clock signal. Further, the sense component of the second dynamic latch may be activated in response to the second transition of the clock signal, and the hold component of the second dynamic latch may be activated in response to the first transition of the clock signal.

### BRIEF DESCRIPTION OF THE DRAWINGS

The present embodiments are illustrated by way of example and are not intended to be limited by the figures of the accompanying drawings, where:

FIG. 1 shows an example frequency divider implemented using multiple CML latches.

FIG. 2 depicts a dynamic latch with a static hold component in accordance with some embodiments.

FIG. 3 is a timing diagram illustrating an example operation of the dynamic latch of FIG. 2.

FIG. 4 depicts a dynamic latch with impedance control circuitry in accordance with some embodiments.

FIG. 5 is a timing diagram illustrating an example operation of the dynamic latch of FIG. 4.

FIGS. 6A-6B depict other embodiments of a dynamic latch with impedance control circuitry.

FIG. 7 depicts a frequency divider implemented using multiple dynamic latches in accordance with some embodiments.

Like reference numerals refer to corresponding parts throughout the drawing figures.

### DETAILED DESCRIPTION

In the following description, numerous specific details are set forth such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present embodiments. However, it will be apparent to one skilled in the art that these specific details may not be required to practice the present embodiments. In other instances, well-known circuits and devices are shown in block diagram form to avoid obscuring the present disclosure. Any of the signals provided over various buses described herein may be time-multiplexed with other signals and provided over one or more common buses. Additionally, the interconnection between circuit elements or software blocks may be shown as buses or as single signal lines. Each of the buses may alternatively be a single signal line, and each of the single signal lines may alternatively be buses, and a single line or bus might represent any one or more of a myriad of physical or logical mechanisms for communication between components. The present embodiments are not to be construed as limited to specific examples described herein but rather to include within their scopes all embodiments defined by the appended claims.

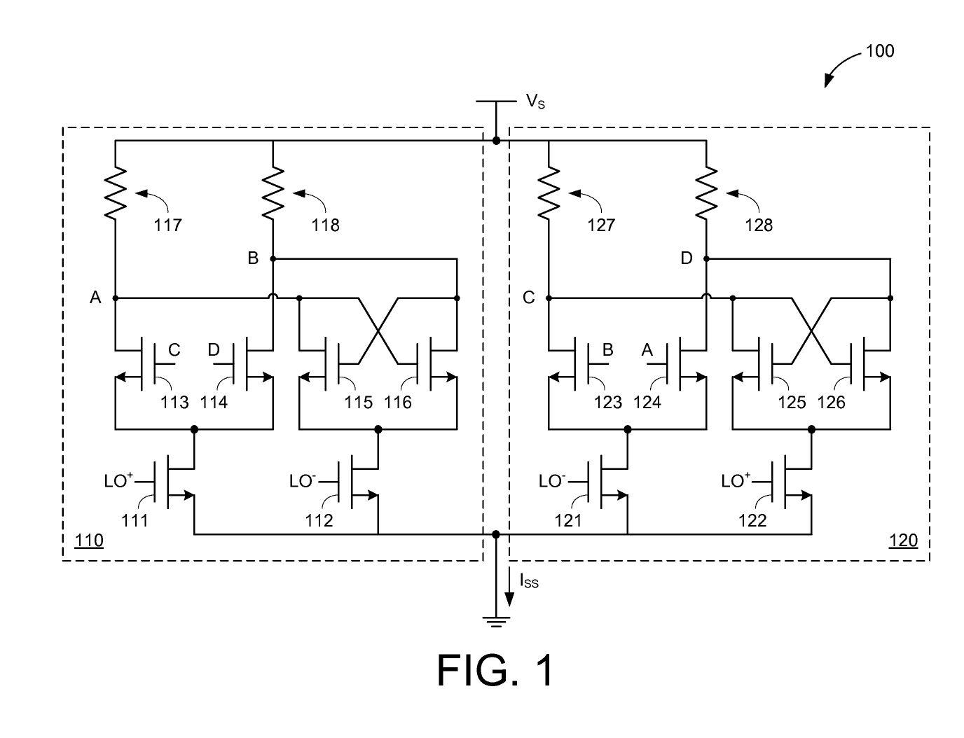

FIG. 1 shows an example frequency divider 100 implemented using multiple CML latches. The frequency divider 100 includes two current mode logic (CML) latches 110 and 120 that are connected in parallel between a voltage source (V_{S}) and ground potential. Each of the CML latches 110 and 120 includes a “sense” component for detecting an input voltage, and includes a “hold” component for retaining the detected voltage. More specifically, the sense component of the first CML latch 110 includes transistors 113 and 114, and the hold component of the first CML latch 110 includes transistors 115 and 116. Similarly, the sense component of the second CML latch 120 includes transistors 123 and 124, and the hold component of the second CML latch 120 includes transistors 125 and 126.

A load resistor 117 is connected between V_{S} and the commonly-coupled drains of transistors 113 and 115, and a load resistor 118 is connected between V_{S} and the commonly-coupled drains of transistors 114 and 116. A load resistor 127 is connected between V_{S} and the commonly-coupled drains of transistors 123 and 125, and a load resistor 128 is connected between V_{S} and the commonly-coupled drains of transistors 124 and 126.

The first CML latch 110 also includes a pair of transistors 111 and 112 to selectively activate the sense component or the hold component of the first CML latch 110 based on a local oscillator (LO) signal. More specifically, the gate of transistor 111 may receive a primary LO signal (LO⁺), and the gate of transistor 112 may receive a complementary LO signal (LO⁻). The second CML latch 120 also includes a pair of transistors 121 and 122 to selectively activate the sense component or the hold component of the second CML latch 120 based on the LO signal. More specifically, the gate of transistor 121 may receive the complementary LO signal (LO⁻), and the gate of transistor 122 may receive the primary LO signal (LO⁺). In this manner, the hold component of the second CML latch 120 may be activated when the sense component of the first CML latch 110 is activated, and the hold component of the first CML latch 110 may be activated when the sense component of the second CML latch 120 is activated.

Because the CML latches 110 and 120 are cross-coupled to each other, the hold component of the second CML latch 120 feeds the sense component of the first CML latch 110, and the hold component of the first CML latch 110 feeds the sense component of the second CML latch 120. More specifically, the first CML latch 110 receives a first input voltage (Vᵢₙ₁) across the gates of transistors 113 and 114 (e.g., Vᵢₙ₁=V_{C}−V_{D}), and generates a first output voltage (Vₒᵤₜ₁) across the drains of transistors 113 and 114 (e.g., Vₒᵤₜ₁=V_{A}−V_{B}). The second CML latch 120 receives a second input voltage (Vᵢₙ₂) across the gates of transistors 123 and 124 (e.g., Vᵢₙ₂=V_{B}−V_{A}), and generates a second output voltage (Vₒᵤₜ₂) across the drains of transistors 113 and 114 (e.g., Vₒᵤₜ₂=V_{C}−V_{D}). The second output voltage generated by the second CML latch 120 is provided as the first input voltage to the first CML latch 110 (e.g., Vᵢₙ₁=Vₒᵤₜ₂), and the first output voltage generated by the first CML latch 110 is provided as the second input voltage to the second CML latch 120 (e.g., Vᵢₙ₂=V_{S}−Vₒᵤₜ₁).

The operation of the frequency divider 100 may be controlled by the LO signal. For example, in response to a rising edge transition of the LO signal (e.g., when LO⁺ is high and LO⁻ is low), the first CML latch 110 senses the output voltage maintained by the second CML latch 120. Thus, if the voltage held by the second CML latch 120 is high (e.g., if V_{C}>V_{D}), then the voltage output by the first CML latch 110 will be low (e.g., then V_{A}<V_{B}), and vice-versa. Then, in response to a falling edge transition of the LO signal (e.g., when LO⁺ is low and LO⁻ is high), the first CML latch 110 holds the voltage detected from the previous LO signal transition (e.g., half-clock cycle), and the second CML latch 120 senses the voltage held by the first CML latch 110. Thus, if the voltage held by the first CML latch 110 is low (e.g., if V_{A}<V_{B}), then the voltage output by the second CML latch 120 will also be low (e.g., then V_{C}<V_{D}), and vice-versa. In this manner, the frequency divider 100 may maintain the same voltage for an entire clock cycle (e.g., until the LO signal transitions states again), thereby generating an output signal that is one-half the frequency of the LO signal.

The frequency divider 100 may continuously draw a tail current (I_{SS}) during its operation. More specifically, both of the CML latches 110 and 120 draw a portion of the tail current I_{SS} regardless of whether each of the CML latches 110 and 120 operates in the sensing mode or in the holding mode. For example, when the first CML latch 110 senses a logic high input voltage (e.g., V_{C}>V_{D}), a portion of the tail current I_{SS} flows through resistor 117 and transistors 113 and 111. Then, when the first CML latch 110 holds the corresponding low output voltage (e.g., V_{A}<V_{B}), a portion of the tail current I_{SS} continues to flow through resistor 117 and transistors 115 and 112. It may thus be desirable to reduce the overall power consumption of the frequency divider 100, for example, by limiting the tail current I_{SS}.

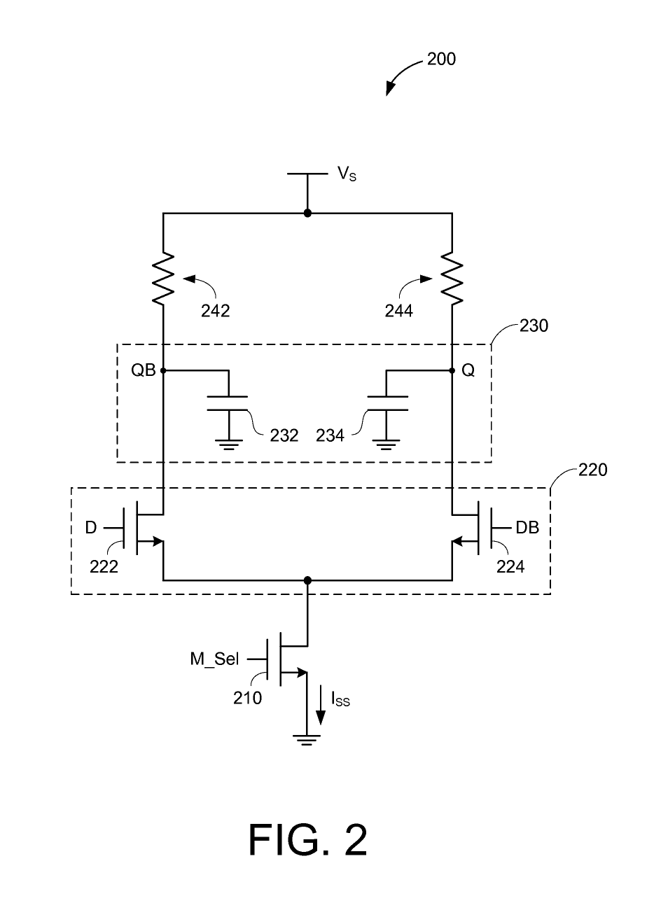

FIG. 2 depicts a dynamic latch 200 with a static hold component in accordance with some embodiments. The dynamic latch 200 includes load resistors 242 and 244, a sense component 220, a hold component 230, and a transistor 210 to selectively activate the sense component 220 or the hold component 230 based on a mode select (M_Sel) signal. More specifically, the sense component 220 may sense or detect an input voltage (e.g., provided by input signal D and its complement DB) when the dynamic latch 200 operates in a sensing mode (e.g., when M_Sel is asserted to logic high), and may generate a corresponding output voltage (e.g., between nodes Q and QB) based, at least in part, on the input voltage. The hold component 230 may hold or retain the output voltage when the dynamic latch 200 operates in a holding mode (e.g., when M_Sel is de-asserted to logic low). For some embodiments, the hold component 230 may retain the output voltage in a static state, for example, so that the dynamic latch 200 does not consume a tail current I_{SS} (or consumes a minimal tail current) when operating in the holding mode.

The sense component 220 includes a pair of transistors 222 and 224 that are coupled between transistor 210 and load resistors 242 and 244, respectively. For purposes of discussion herein, the sense component 220 may become “activated” when transistor 210 is turned on (e.g., when M_Sel is asserted), thereby allowing the tail current I_{SS} to flow from V_{S}, through the sense component 220 and transistor 210, to ground potential. More specifically, the tail current I_{SS} may flow through one of the transistors 222 or 224 depending on the polarity of the input voltage. For example, the sense component 220 may receive a differential input voltage across the gates of the transistors 222 and 224 (e.g., Vᵢₙ=V_{D}−V_{DB}), and may generate a differential output voltage across the drains of the transistors 222 and 224 (e.g., Vₒᵤₜ=V_{Q}−V_{QB}) based on the input voltage. When the differential input voltage is positively biased (e.g., when V_{D}>V_{DB}), the tail current I_{SS} flows (at least primarily) through transistor 222. Conversely, when the differential input voltage is negatively biased (e.g., when V_{D}<V_{DB}), the tail current I_{SS} flows (at least primarily) through transistor 224.

The hold component 230 includes a pair of capacitors 232 and 234 that are coupled between ground potential and the drains of transistors 222 and 224, respectively. For purposes of discussion herein, the hold component 230 may become “activated” when transistor 210 is turned off (e.g., when M_Sel is de-asserted), which in turn prevents transistor 210 from drawing current through the dynamic latch 200. More specifically, the capacitors 232 and 234 may charge to and/or discharge from the output voltage level (e.g., Vₒᵤₜ=V_{Q}−V_{QB}) when the dynamic latch 200 operates in the sensing mode (e.g., when M_Sel is asserted), and the capacitors 232 and 234 may maintain the output voltage in a static state when the dynamic latch 200 operates in the holding mode (e.g., when M_Sel is de-asserted). For other embodiments, the capacitors 232 and 234 may be supplemented by and/or substituted with other circuitry that is to retain voltage information in a static state.

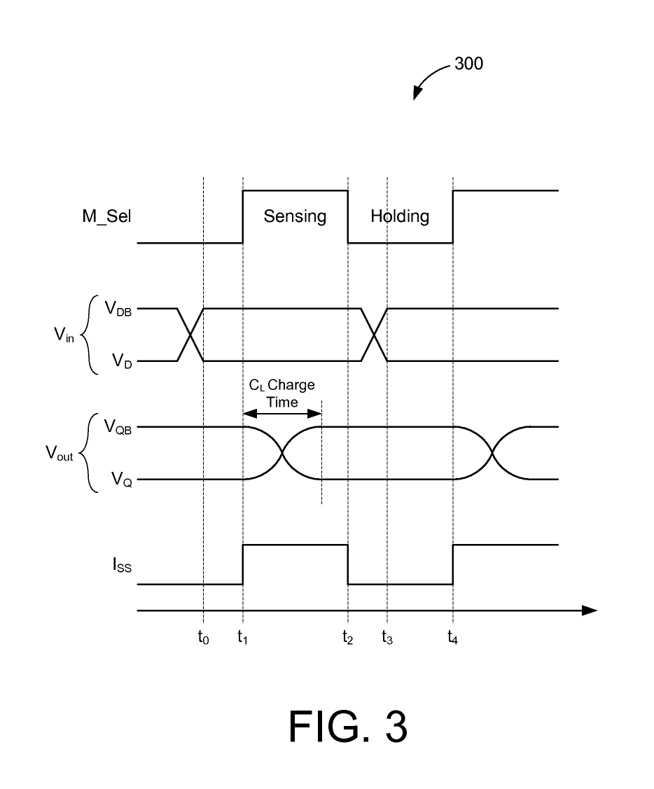

FIG. 3 is a timing diagram 300 illustrating an example operation of the dynamic latch 200 of FIG. 2. For example, when the input voltage Vᵢₙ first becomes positively biased (at time t₀), the M_Sel signal is de-asserted and little or no tail current I_{SS} flows through the dynamic latch 200. Accordingly, the output voltage Vₒᵤₜ does not change (from its previous state).

When the M_Sel signal is asserted (at time t₁), the tail current I_{SS} flows through the dynamic latch 200 and causes the output voltage Vₒᵤₜ to track the input voltage Vᵢₙ. More specifically, because the input voltage Vᵢₙ is positively biased (e.g., V_{D}>V_{DB}), the tail current I_{SS} may flow primarily through the leftmost branch of the dynamic latch 200 (e.g., through resistor 242 and transistor 222). Current flow through resistor 242 and transistor 222 causes the voltage at node QB to be pulled low (e.g., V_{QB}=0), which in turn causes the capacitor 232 to discharge low towards ground potential. Because of the positively biased input voltage Vᵢₙ, little or no tail current I_{SS} flows through the rightmost branch of the dynamic latch 200 (e.g., through resistor 244 and transistor 224). The lack of current flow through resistor 244 and transistor 224 causes the voltage at node Q to be pulled high (e.g., V_{Q}=V_{S}), which in turn charges capacitor 234 high towards V_{S}.

When the M_Sel signal is de-asserted (at time t₂), the non-conducting transistor 210 cuts off the tail current I_{SS}. The output voltage Vₒᵤₜ may not change because capacitors 232 and 234 may continue to hold or retain the output voltage Vₒᵤₜ in a static state. The dynamic latch 200 may continue to maintain the output voltage Vₒᵤₜ from the previous sensing state (e.g., just prior to time t₂) even after the polarity of the input voltage Vᵢₙ reverses (at time t₃), as long as the M_Sel signal remains de-asserted (e.g., to maintain transistor 210 in a non-conductive state).

Then, when the M_Sel signal is asserted again (at time t₄), the conductive state of transistor 210 allows the tail current I_{SS} to flow through the dynamic latch 200, thereby allowing the output voltage Vₒᵤₜ to track the input voltage Vᵢₙ. More specifically, because the input voltage Vᵢₙ is now negatively biased (e.g., V_{D}<V_{DB}), the tail current I_{SS} flows primarily through the rightmost branch of the dynamic latch 200. As a result, the voltage at node Q is pulled low (e.g., V_{Q}=0) by transistors 224 and 210, which in turn causes capacitor 234 to discharge low towards ground potential. The negatively biased input voltage Vᵢₙ turns off transistor 222, and thus little or no tail current I_{SS} flows through the leftmost branch of the dynamic latch 200. As a result, the voltage at node QB is pulled high (e.g., V_{QB}=V_{S}), which in turn causes capacitor 232 to charge high towards V_{S}.

By holding the output voltage in a static state, the dynamic latch 200 may draw approximately one-half the tail current I_{SS} (and thus consume approximately one-half the power) per clock cycle, as compared to conventional CML latches such as CML latch 110, 120 of FIG. 1. The voltage swing of the output voltage Vₒᵤₜ may be limited by the time required to charge and/or discharge the capacitors 232 and 234 (e.g., the C_{L} charge time). For example, if a switching time of the M_Sel signal is shorter than the C_{L} charge time, then the output voltage Vₒᵤₜ may not properly track the input voltage Vᵢₙ. Accordingly, the performance of dynamic latch 200 may decrease for higher frequency clock divider applications.

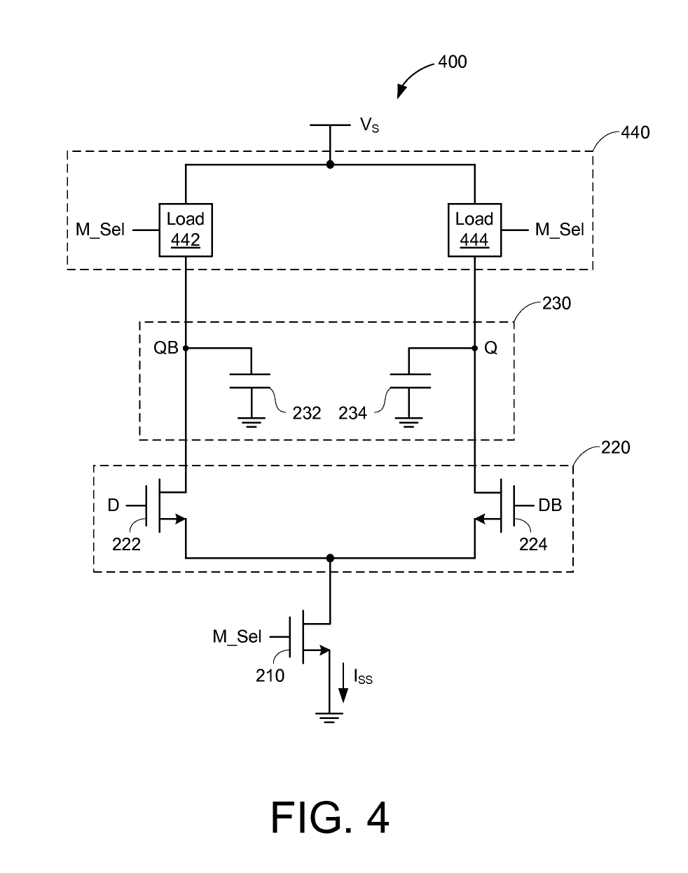

FIG. 4 depicts a dynamic latch 400 with impedance control circuitry in accordance with some embodiments. The dynamic latch 400 includes an impedance controller 440 including load elements 442 and 444, and includes the sense component 220, the hold component 230, and the transistor 210 of FIG. 2. As described above with respect to FIG. 2, the sense component 220 may sense or detect a differential input voltage between the gates of transistors 222 and 224 when the dynamic latch 400 operates in the sensing mode (e.g., when M_Sel is asserted to logic high), and may generate a differential output voltage between nodes Q and QB. The hold component 230 may hold or retain the output voltage when the dynamic latch 400 operates in the holding mode (e.g., when M_Sel is de-asserted to logic low). For some embodiments, the hold component 230 may retain the output voltage in a static state, for example, so that the dynamic latch 400 consumes very little or no tail current I_{SS} when operating in the holding mode.

The sense component 220 includes a pair of transistors 222 and 224 that are coupled between transistor 210 and the impedance controller 440. The hold component 230 includes a pair of capacitors 232 and 234 that are also coupled to the impedance controller 440. The impedance controller 440 may control and/or vary the impedance of load elements 442 and 444 of the dynamic latch 400 based on the M_Sel signal (e.g., which may determine the operating mode of dynamic latch 400). For some embodiments, the impedance controller 440 may reduce the load impedance when the dynamic latch 400 operates in the sensing mode (e.g., when the M_Sel signal is asserted). As described in more detail below, reducing the load impedance may reduce the time for the hold component 230 to latch the output voltage provided between nodes Q and QB.

Conversely, the impedance controller 440 may increase the load impedance when the dynamic latch 400 operates in the holding mode (e.g., when the M_Sel signal is de-asserted). As described in more detail below, increasing the load impedance may allow the hold component 230 to retain the output voltage for longer durations (e.g., as compared with embodiments that do not increase the load impedance during the holding mode).

The impedances of the load elements 442 and 444 may be adjusted or varied based, at least in part, on the M_Sel signal. For example, when the dynamic latch 400 operates in the sensing mode, assertion of the M_Sel signal may place the load elements 442 and 444 in a low-impedance state. The low-impedance state of load elements 442 and 444 may increase the amount of current through capacitors 232 and/or 234, thereby increasing the charging rate (and discharging rate) of the capacitors 232 and/or 234. When the dynamic latch 400 operates in the holding mode, de-assertion of the M_Sel signal places the load elements 442 and 444 in a high-impedance state. The high-impedance state of load elements 442 and 444 may prevent current leakage through the capacitors 232 and 234, thereby allowing the capacitors 232 and 234 to retain the output voltage for longer durations.

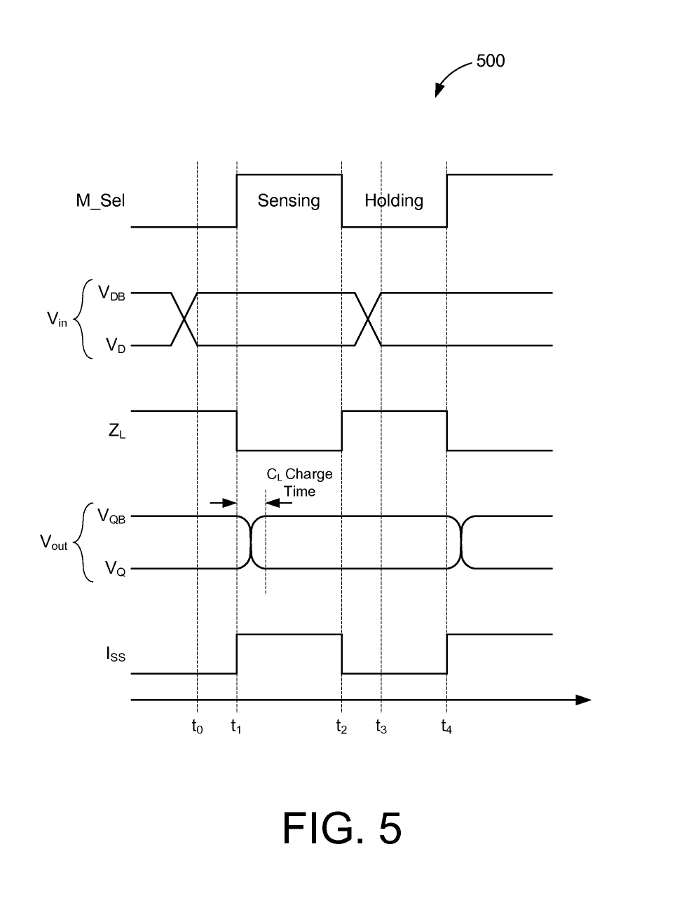

FIG. 5 is a timing diagram 500 illustrating an example operation of the dynamic latch 400 of FIG. 4. For example, when the input voltage Vᵢₙ is initially biased positively (at time t₀), the M_Sel signal is de-asserted and, as described above, little or no tail current I_{SS} flows through the dynamic latch 400. The de-asserted state of the M_Sel signal places the load elements 442 and 444 in a high-impedance state (e.g., is above a threshold level), which in turn may prevent the output voltage Vₒᵤₜ from changing from its previous state.

When the M_Sel signal is asserted (at time t₁), the load elements 442 and 444 are placed in a low-impedance state (e.g., is below the threshold level), thereby allowing the tail current I_{SS} to flow through the dynamic latch 400 and causing the output voltage Vₒᵤₜ to track the input voltage Vᵢₙ. Because the input voltage Vᵢₙ is positively biased (e.g., V_{D}>V_{DB}), the voltage at node QB is pulled low (e.g., V_{QB}=0), which in turn causes the capacitor 232 to discharge low towards ground potential. More specifically, the low-impedance state of load elements 442 and 444 may cause the capacitor 232 to discharge at a faster rate than capacitor 232 of FIG. 2. At the same time, the voltage at node Q is pulled high (e.g., V_{Q}=V_{S}), which in turn causes the capacitor 234 to charge high towards V_{S}. More specifically, the low-impedance state of load elements 442 and 444 may allow the capacitor 234 to charge towards V_{S} at a faster rate than capacitor 232 of FIG. 2.

When the M_Sel is again de-asserted (at time t₂), the load elements 442 and 444 are placed in the high-impedance state, and the non-conductive transistor 210 prevents the tail current I_{SS}. The output voltage Vₒᵤₜ does not change because the capacitors 232 and 234 may continue to hold or retain the output voltage Vₒᵤₜ in a static state. More specifically, the high-impedance state of load elements 442 and 444 may reduce leakage current from the capacitors 232 and 234, thereby allowing the capacitors 232 and 234 to retain their respective charges for longer durations. The dynamic latch 400 may maintain the output voltage Vₒᵤₜ from the previous sensing state (e.g., just prior to time t₂) even after the polarity of the input voltage Vᵢₙ reverses (at time t₃), as long as the M_Sel signal remains de-asserted.

Then, when the M_Sel signal is again asserted (at time t₄), transistor 210 is conductive and allows the tail current I_{SS} flow through the dynamic latch 400, thereby allowing the output voltage Vₒᵤₜ to track the input voltage Vᵢₙ. Because the input voltage Vᵢₙ is now negatively biased (e.g., V_{D}<V_{DB}), the voltage at node QB is pulled high (e.g., V_{QB}=V_{S}), which in turn causes capacitor 232 to charge high towards V_{S}. More specifically, the low-impedance state of load elements 442 and 444 may allow the capacitor 232 of FIG. 4 to charge at a faster rate than the capacitor 232 of FIG. 2. At the same time, the voltage at node Q is pulled low (e.g., V_{Q}=0), which in turn causes the capacitor 234 to discharge low towards ground potential. More specifically, the low-impedance state of load elements 442 and 444 may allow the capacitor 234 of FIG. 4 to discharge at a faster rate than the capacitor 232 of FIG. 2.

Accordingly, dynamically adjusting the impedance Z_{L} of load elements 442 and 444 may improve performance of the dynamic latch 400 for both low-frequency and high-frequency clock divider applications. More specifically, reducing the load impedance Z_{L} (e.g., to the low-impedance state) when the dynamic latch 400 operates in the sensing mode may reduce the time required to charge and/or discharge the capacitors 232 and 234 (e.g., the C_{L} charge time), which is important for high-frequency clock applications in which the switching time of the M_Sel signal is relatively short (e.g., increasing the charging rate and/or the discharging rate of the output nodes Q and QB may allow the dynamic latch 400 to operate at higher frequencies than conventional latches such as, for example, non-modulating load latches. Further, increasing the load impedance Z_{L} (e.g., to the high-impedance state) when the dynamic latch 400 operates in the holding mode may allow the capacitors 232 and 234 to retain their charges for longer durations, which is important for low-frequency clock applications in which the switching time of the M_Sel signal is relatively long (e.g., increasing the time duration for which the output nodes Q and QB hold their respective charges may allow the dynamic latch 400 to operate at lower frequencies than conventional CML latches). Thus, by reducing the load impedance Z_{L} when the dynamic latch 400 operates in the sensing mode and by increasing the load impedance Z_{L} when the dynamic latch 400 operates in the holding mode may widen the frequency operating range of dynamic latch 400 (e.g., as compared to conventional latches such as, for example, non-modulating load latches).

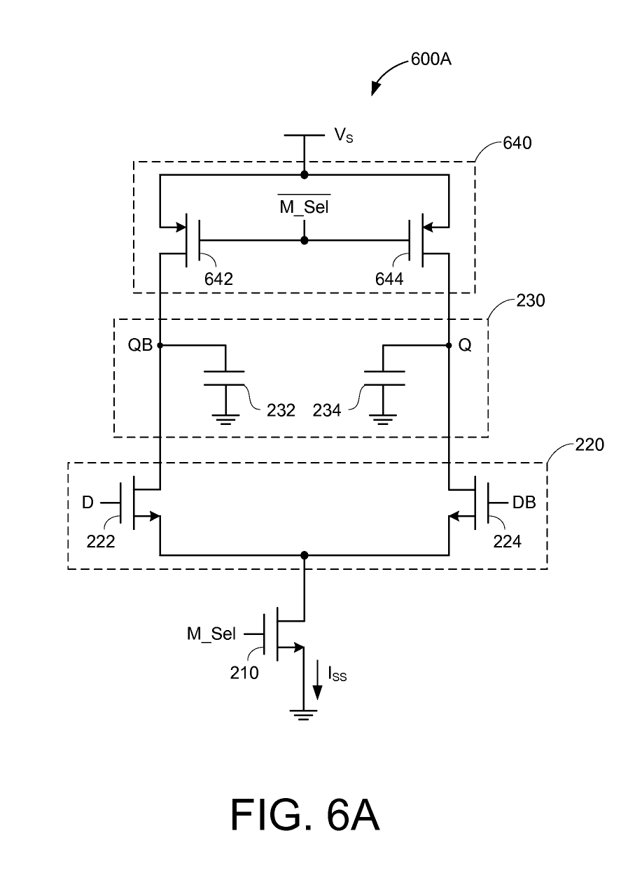

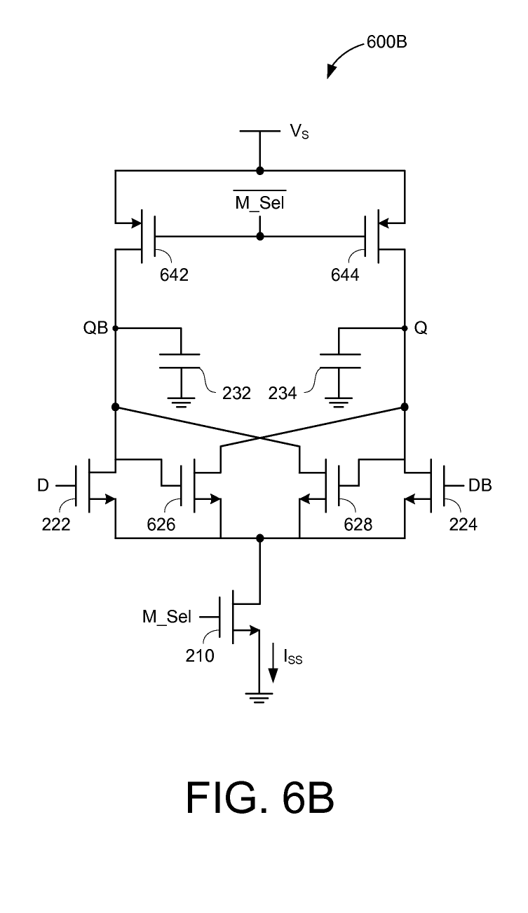

FIG. 6A depicts a dynamic latch 600A with impedance control circuitry in accordance with other embodiments. The dynamic latch 600A includes an impedance controller 640 including load transistors 642 and 644, and includes the sense component 220, the hold component 230, and the transistor 210. As described above with respect to FIG. 2, the sense component 220 may sense or detect a differential input voltage when the dynamic latch 600A operates in the sensing mode (e.g., when M_Sel is asserted to logic high), and may generate a differential output voltage based, at least in part, on the differential input voltage. The hold component 230 may hold or retain the output voltage when the dynamic latch 600A operates in the holding mode (e.g., when M_Sel is de-asserted). For some embodiments, the hold component 230 may retain the output voltage in a static state, for example, so that the dynamic latch 600A consumes very little or no tail current I_{SS} when operating in the holding mode.

The impedance controller 640 may control and/or vary the impedance of load transistors 642 and 644 of the dynamic latch 600A based on the operating mode of the dynamic latch (e.g., as determined by the logical state of the M_Sel signal). More specifically, the load transistors 642 and 644, which are coupled between V_{S} and respective nodes QB and Q of the holding component 230, may be biased and/or configured to operate in the triode region. For example, each of the load transistors 642 and 644 may be biased such that (1) its gate-to-source voltage is greater than its threshold voltage and (2) its drain-to-source voltage is less than the difference between its gate-to-source voltage and its threshold voltage. For some embodiments, the load transistors 642 and 644 may be programmatically biased to compensate for process, voltage, and/or temperature (PVT) variations. By operating the transistors 642 and 644 in the triode region, the current flowing through each of transistors 642 and 644 may be controlled by its gate voltage, which in turn allows the load transistors 642 and 644 to operate as variable-impedance resistors or loads (e.g., such as described above with respect to the load elements 442 and 444 of FIG. 4).

For some embodiments, the load transistors 642 and 644 may be p-channel metal-oxide-semiconductor (PMOS) transistors having source terminals coupled to V_{S} and drain terminals coupled to nodes QB and Q, respectively. The gate terminals of the load transistors 642 and 644 may be coupled to receive a complemented mode select signal (e.g., M_Sel), for example, where the M_Sel is the logic complement of the M_Sel signal. Accordingly, the impedances of load transistors 642 and 644 may be adjusted based on the M_Sel signal.

For example, when the dynamic latch 600A operates in the sensing mode (e.g., when M_Sel is asserted and M_Sel is de-asserted), the p-channels of load transistors 642 and 644 are in a low-impedance state, which in turn allows respective capacitors 232 and 234 of FIG. 6A to charge at a faster rate than capacitors 232 and 234 of FIG. 2. In this manner, the dynamic latch 600A may latch the output voltage faster than the dynamic latch 200 of FIG. 2. When the dynamic latch 600A operates in the holding mode (e.g., when M_Sel is de-asserted and M_Sel is asserted), the p-channels of load transistors 642 and 644 are in a high-impedance state, which in turn allows respective capacitors 232 and 234 of FIG. 6A to hold their charges longer than capacitors 232 and 234 of FIG. 2.

FIG. 6B shows a dynamic latch 600B in accordance with other embodiments. In addition to all the elements of dynamic latch 600A of FIG. 6A, the dynamic latch 600B includes an additional pair of transistors 626 and 628. The transistors 626 and 628 are cross-coupled between nodes Q and QB, and may provide positive feedback during sensing operations. For example, transistor 626 has a drain terminal coupled to node Q, a gate terminal coupled to node QB, and a source terminal coupled to the transistor 210. The transistor 628 has a drain terminal coupled to node QB, a gate terminal coupled to node Q, and a source terminal coupled to the transistor 210. The addition of transistors 626 and 628 may improve the performance of dynamic latch 600B, as compared to the dynamic latch 600A of FIG. 6A, by providing increased noise threshold immunity and/or switching speed.

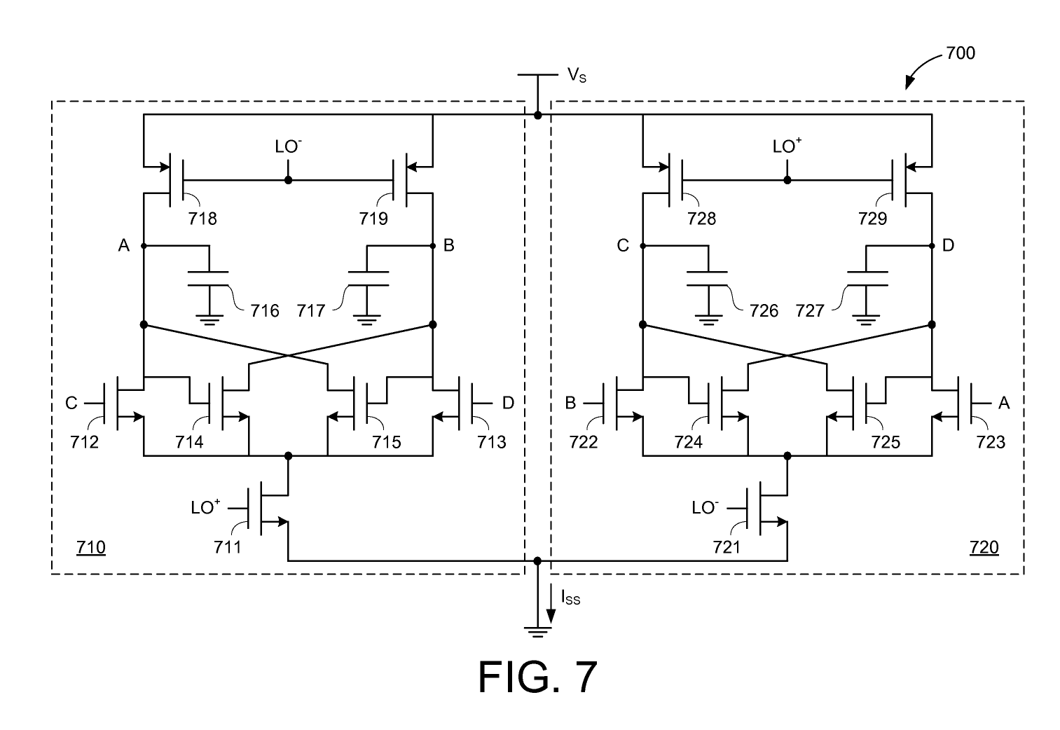

FIG. 7 depicts a frequency divider 700 implemented using two dynamic latches in accordance with some embodiments. The frequency divider 700 includes two dynamic latches 710 and 720 connected in parallel between V_{S} and ground potential. For purposes of discussion herein, the dynamic latches 710 and 720 may each be one embodiment of dynamic latch 600B of FIG. 6B. However, it should be noted that the dynamic latches 710 and 720 may be any of the dynamic latches described above with respect to FIGS. 2, 4, and 6A-6B). As described above with respect to FIG. 6B, each of the dynamic latches 710 and 720 includes a sense component for detecting an input voltage, and a hold component for retaining the detected voltage in a static state. More specifically, the sense component of the first dynamic latch 710 includes transistors 712-715, and the hold component of the first dynamic latch 710 includes capacitors 716 and 717. Similarly, the sense component of the second dynamic latch 720 includes transistors 722-725, and the hold component of the second dynamic latch 720 includes capacitors 726 and 727. The first dynamic latch 710 also includes load transistors 718 and 719 (e.g., coupled between node A and Vs and between node B and Vs, respectively). The second dynamic latch 720 also includes load transistors 728 and 729 (e.g., coupled between node C and Vs and between node DB and Vs, respectively).

The first dynamic latch 710 includes a transistor 711 to selectively activate the sense component or the hold component of the first dynamic latch 710 based on a local oscillator (LO) signal. For example, the gate of transistor 711 may receive a primary LO signal (LO⁺). The second dynamic latch 720 includes a transistor 721 to selectively activate the sense component or the hold component of the second dynamic latch 720 based on the LO signal. For example, the gate of the transistor 721 may receive a complementary LO signal (LO⁻). In this manner, the hold component of the second dynamic latch 720 may be activated when the sense component of the first dynamic latch 710 is activated, and the hold component of the first dynamic latch 710 may be activated when the sense component of the second dynamic latch 720 is activated.

The dynamic latches 710 and 720 are cross-coupled to one another, for example, so that the hold component of second dynamic latch 720 feeds the sense component of first dynamic latch 710, and the hold component of first dynamic latch 710 feeds the sense component of second dynamic latch 720. More specifically, the first dynamic latch 710 may receive an input voltage (Vᵢₙ₁) across the gates of transistors 712 and 713 (e.g., Vᵢₙ₁=V_{C}−V_{D}), and may generate an output voltage (Vₒᵤₜ₁) across the drains of transistors 712 and 713 (e.g., Vₒᵤₜ₁=V_{A}−V_{B}). The second dynamic latch 720 may receive an input voltage (Vᵢₙ₂) across the gates of transistors 722 and 723 (e.g., Vᵢₙ₂=V_{B} V_{A})) and may generate an output voltage (Vₒᵤₜ₂) across the drains of transistors 722 and 723 (e.g., Vₒᵤₜ₂=V_{C}−V_{D}). In this manner, the output voltage generated by the second dynamic latch 720 may be provided as the input voltage to the first dynamic latch 710 (e.g., Vᵢₙ₁=Vₒᵤₜ₂), and the output voltage generated by the first dynamic latch 710 may be provided as the complementary input voltage to the second dynamic latch 720 (e.g., Vᵢₙ₂=V_{S} Vₒᵤₜ₁).

The operation of the frequency divider 700 may be controlled by the LO signal. For example, in response to a rising edge transition of the LO signal (e.g., when LO⁺ is high and LO⁻ is low), the first dynamic latch 710 senses the output voltage (Vₒᵤₜ₂) maintained by the second dynamic latch 720. More specifically, the first dynamic latch 710 senses the voltage differential between the capacitors 726 and 727 (e.g., V_{C} and V_{D}, respectively). If the output voltage (Vₒᵤₜ₂) of the second dynamic latch 720 is high (e.g., V_{C}>V_{D}), then the output voltage (Vₒᵤₜ₁) of the first dynamic latch 710 is pulled low (e.g., V_{A}<V_{B}), and vice-versa. It should be noted that the polarity of the output voltage of the first dynamic latch 710 is opposite that of the input voltage of the first dynamic latch 710 (e.g., Vₒᵤₜ₁˜−Vᵢₙ₁).

In response to a falling edge transition of the LO signal (e.g., when LO⁺ is low and LO⁻ is high), the first dynamic latch 710 holds the output voltage from the previous LO signal transition (e.g., half-clock cycle), and the second dynamic latch 720 senses the complement of the output voltage maintained by the first dynamic latch 710. More specifically, the second dynamic latch 720 senses the voltage differential between the capacitors 717 and 716 (e.g., V_{B} and V_{A}, respectively). If the output voltage of the first dynamic latch 710 is low (e.g., V_{A}<V_{B}), then the output voltage of the second dynamic latch 720 remains low (e.g., V_{C}<V_{D}), and vice-versa. In this manner, the frequency divider 700 may maintain the same output voltage (e.g., Vₒᵤₜ₁ and Vₒᵤₜ₂) for an entire clock cycle (e.g., until the LO signal transitions high again), thereby generating an output signal that is one-half the frequency of the LO signal.

Each of the dynamic latches 710 and 720 consumes very little or no tail current I_{SS} when operating in the holding mode. Further, the frequency divider 700 is configured such that whenever one of the dynamic latches 710 or 720 operates in the sensing mode, the other of the dynamic latches 710 and 720 operates in the holding mode. Accordingly, only of the dynamic latches 710 or 720 may consume the tail current I_{SS} at any given time. As a result, the frequency divider 700 may consume only one-half the power consumed by frequency dividers implemented using conventional CML latches (e.g., such as frequency divider 100 of FIG. 1).

In the foregoing specification, the present embodiments have been described with reference to specific example embodiments thereof. It will, however, be evident that various modifications and changes may be made thereto without departing from the broader scope of the disclosure as set forth in the appended claims. The specification and drawings are, accordingly, to be regarded in an illustrative sense rather than a restrictive sense.

What is claimed is:

1. A dynamic latch comprising:
a sense component to detect an input voltage in response to a first state of a mode select signal, and to generate an output voltage based, at least in part, on the input voltage;
a hold component to retain the output voltage in response to a second state of the mode select signal; and
a first transistor, coupled between the sense component and ground potential, including a gate responsive to the mode select signal.

2. The dynamic latch of claim 1, wherein the dynamic latch is to operate in a sensing mode when the mode select signal is in the first state, and wherein dynamic latch is to operate in a holding mode when the mode select signal is in the second state.

3. The dynamic latch of claim 1, wherein the first transistor is to provide a tail current based, at least in part, on the mode select signal.

4. The dynamic latch of claim 1, wherein the sense component comprises one or more second transistors to control a flow of current through the dynamic latch based, at least in part, on the input voltage.

5. The dynamic latch of claim 1, wherein the hold component comprises one or more capacitors to retain the output voltage in a static state.

6. The dynamic latch of claim 1, further comprising:
an impedance controller to vary a load impedance of the dynamic latch based, at least in part, on the mode select signal.

7. The dynamic latch of claim 6, wherein the impedance controller is to decrease the load impedance when the mode select signal is in the first state, and is to increase the load impedance when the mode select signal is in the second state.

8. The dynamic latch of claim 6, wherein the impedance controller comprises one or more load transistors operating in a triode mode.

9. The dynamic latch of claim 8, wherein a respective one of the load transistors comprises:
a source terminal coupled to a voltage source;
a drain terminal coupled to the hold component; and
a gate terminal responsive to the mode select signal.

10. A frequency divider comprising:
a plurality of dynamic latches to operate in either a sensing mode or a holding mode, wherein a respective one of the plurality of dynamic latches includes:
a sense component that, when the respective dynamic latch operates in the sensing mode, is to detect an input voltage and to generate an output voltage based, at least in part, on the input voltage;
a hold component that, when the respective dynamic latch operates in the holding mode, is to retain the output voltage; and
a first transistor, coupled between the sense component and ground potential, including a gate responsive to a mode select signal.

11. The frequency divider of claim 10, wherein the sense component comprises one or more second transistors to control a flow of current through the respective dynamic latch based, at least in part, on the input voltage.

12. The frequency divider of claim 10, wherein the hold component comprises one or more capacitors to retain the output voltage in a static state.

13. The frequency divider of claim 10, wherein the respective dynamic latch further comprises:
an impedance controller to vary a load impedance of the respective dynamic latch based, at least in part, on the mode select signal.

14. The frequency divider of claim 13, wherein the impedance controller is to decrease the load impedance when the mode select signal indicates the sensing mode, and is to increase the load impedance when the mode select signal indicates the holding mode.

15. The frequency divider of claim 13, wherein the impedance controller comprises a variable load coupled between a voltage source and the hold component of the respective dynamic latch, and wherein the load impedance is controlled, at least in part, by a clock signal.

16. The frequency divider of claim 15, wherein the variable load includes at least one transistor comprising:
a source terminal coupled to the voltage source;
a drain terminal coupled to the hold component of the respective dynamic latch; and
a gate terminal coupled to a complementary clock signal, wherein the complementary clock signal is a complement of the clock signal.

17. The frequency divider of claim 10, wherein each of the plurality of dynamic latches is to alternate between the sensing mode and the holding mode based, at least in part, on a clock signal.

18. The frequency divider of claim 10, wherein the plurality of dynamic latches includes a first latch and a second latch, and wherein the first latch is cross coupled to the second latch such that:
the output voltage of the first latch is provided as the input voltage to the second latch; and
the output voltage of the second latch is provided as the input voltage to the first latch.

19. The frequency divider of claim 18, wherein the sense component of the first latch is activated in response to a first transition of a clock signal, and wherein the hold component of the first latch is activated in response to a second transition of the clock signal.

20. The frequency divider of claim 19, wherein the sense component of the second latch is activated in response to the second transition of the clock signal, and wherein the hold component of the second latch is activated in response to the first transition of the clock signal.
